(19) United States
(12) Patent Application Publication
(10) Pub. No.: US 2013/0161665 A1
(43) Pub. Date: Jun. 27, 2013

(54) LIGHT-EMITTING DEVICE AND SURFACE LIGHT SOURCE DEVICE USING SAME

(71) Applicants: Takashi Kuwaharada, Kagoshima (JP); Tooru Aoyagi, Kagoshima (JP); Tomoyuki Kusano, Kagoshima (JP)

(72) Inventors: Takashi Kuwaharada, Kagoshima (JP); Tooru Aoyagi, Kagoshima (JP); Tomoyuki Kusano, Kagoshima (JP)

(73) Assignee: PANASONIC CORPORATION, Osaka (JP)

(21) Appl. No.: 13/820,634

(22) PCT Filed: Oct. 13, 2011
(86) PCT No.: PCT/JP2011/005739

§ 371 Date: Mar. 4, 2013

(30) Foreign Application Priority Data
Oct. 14, 2010 (JP) 2010-231242

(51) Int. Cl. H01L 33/60

(52) U.S. Cl. CPC H01L 33/60
USPC 257/88; 257/98

(57) ABSTRACT

A light emitting device includes: a light-emitting element 110 fixed onto a board 112 and having a light emission region that faces upward; and a light-control lens 114 located above the light-emitting element 110 and having an optical axis L that coincides with an optical axis of the light emission region. The light-control lens 114 includes a recess 141a located around the optical axis L, a first reflective surface that is located in the recess 141a and totally reflects light incident from the light emission region in a direction away from the optical axis L, and a first refractive surface that is located outside the first reflective surface in the recess 141a and refracts light incident from the light emission region at an emission angle larger than an incident angle of the light.

### TECHNICAL FIELD

The present disclosure relates to light emitting devices and surface light source devices, and more particularly to a light emitting device including a light-control lens for adjusting light distribution and a surface light source device using the light emitting device.

### BACKGROUND ART

Liquid crystal panels for use in, for example, thin liquid-crystal television sets generally employ backlight devices that illuminate the panels from behind. Since it is required for a backlight device to uniformly illuminate a liquid crystal panel with a large display area, a surface light source device in which light emitting devices are arranged in a lattice with predetermined spacing on, for example, a printed wiring board is employed. Light emitting devices for use in surface light source devices need to have light distribution characteristics capable of efficiently distributing light to a predetermined range.

A light emitting device including, for example, a light-control lens for adjusting distribution of light emitted from a light-emitting element in order to efficiently distribute light is proposed (see, for example, Patent Document 1). For example, as illustrated in FIGS. 15(a) and 15(b), the use of a light-control lens in which the ratio of an emission angle θ2 to an incident angle θ1 (θ2/θ1) is higher than 1 (one) and, as the incident angle θ1 increases, the ratio θ2/θ1 gradually decreases, except for a region near an optical axis (immediately above the light-emitting element) L may allow light to be uniformly and smoothly distributed to a predetermined optical illumination range.

### CITATION LIST

### Patent Document

[Patent Document 1] Japanese Patent Publication No. 2006-324256

### SUMMARY OF THE INVENTION

### Technical Problem

The light emitting device using the conventional light-control lens described above, however, has the following problems. In the conventional light-control lens, light at an incident angle θ1 close to 0 (zero), i.e., light emitted immediately upward from the light-emitting element, is still emitted immediately upward from the light-emitting element without change because of a small emission angle θ2. On the other hand, as the luminance of the light-emitting element increases, an optical output of the light-emitting element significantly increases. In addition, the light-emitting element has a maximum emission intensity immediately above the light-emitting element. Thus, in a light-emitting element with a high luminance, the luminance immediately above the light-emitting element, i.e., near an optical axis of a light-control lens, greatly increases as compared to the luminances in its periphery, thus making it difficult to eliminate variations in luminance.

It is therefore an object of the present disclosure to provide a light emitting device with a wide optical illumination range and reduced variations in luminance.

### Solution to the Problem

To achieve the object, a light emitting device according to the present disclosure includes a light-control lens having a reflective surface located around an optical axis and totally reflecting incident light and a refractive surface located around the reflective surface and refract incident light in a direction way from the optical axis.

Specifically, a light emitting device according to the present disclosure includes: a light-emitting element fixed onto a board and having a light emission region that faces upward; and a light-control lens located above the light-emitting element and having an optical axis that coincides with an optical axis of the light emission region, wherein the light-control lens includes a recess located around the optical axis, a first reflective surface that is located in the recess and totally reflects light incident from the light emission region in a direction away from the optical axis, and a first refractive surface that is located outside the first reflective surface in the recess and refracts light incident from the light emission region at an emission angle larger than an incident angle of the light.

### Advantages of the Invention

According to the present disclosure, a light emitting device with a wide optical illumination range and reduced variations in luminance can be provided.

### BRIEF DESCRIPTION OF THE DRAWINGS

FIG. 1 is a cross-sectional view illustrating a surface light source device according to an embodiment.

FIG. 2 is a plan view illustrating an example of arrangement of light emitting devices.

FIGS. 3(a)-3(c) illustrate a light emitting device according to the embodiment, FIG. 3(a) is a plan view, FIG. 3(b) is a cross-sectional view taken along line IIIb-IIIb in FIG. 3(a), and FIG. 3(c) is a cross-sectional view taken along line IIIc-IIIc in FIG. 3(a).

FIGS. 4(a) and 4(b) illustrate an example of a lead frame, FIG. 4(a) is a plan view, and FIG. 4(b) is a bottom view.

FIGS. 5(a)-5(c) illustrate the light emitting device of the embodiment except for a light-control lens, FIG. 5(a) is a plan view, FIG. 5(b) is a cross-sectional view taken along line Vb-Vb in FIG. 5(a), and FIG. 5(c) is a cross-sectional view taken along line Vc-Vc in FIG. 5(a).

FIGS. 6(a) and 6(b) illustrate an example of a lead frame assembly, FIG. 6(a) is a plan view, and FIG. 6(b) is a bottom view.

FIG. 7 is a cross-sectional view illustrating an example of a process step of forming a resin encapsulating part.

FIG. 8 is a cross-sectional view illustrating an arrangement of a region in a light emission surface of a light-control lens.

FIG. 9 is a graph showing light emission characteristics in the light emission surface of the light-control lens.

FIG. 10 is a view for defining an incident angle and an emission angle.

FIG. 11 is a cross-sectional view showing light emission characteristics in the light emission surface of the light-control lens.

FIG. 12 shows light distribution characteristics of the light emitting device of the embodiment.

FIG. 13 is a cross-sectional view illustrating a variation of the light emitting device of the embodiment.

FIGS. 14(a)-14(c) are perspective views illustrating examples of connection of wires to light-emitting elements.

FIG. 15(a) is a graph showing light emission characteristics of a conventional light-control lens, and FIG. 15(b) is a view for describing an incident angle and an emission angle.

### DESCRIPTION OF EMBODIMENTS

An example light emitting device includes: a light-emitting element fixed onto a board and having a light emission region that faces upward; and a light-control lens located above the light-emitting element and having an optical axis that coincides with an optical axis of the light emission region, wherein the light-control lens includes a recess located around the optical axis, a first reflective surface that is located in the recess and totally reflects light incident from the light emission region in a direction away from the optical axis, and a first refractive surface that is located outside the first reflective surface in the recess and refracts light incident from the light emission region at an emission angle larger than an incident angle of the light.

The example light emitting device includes the first reflective surface that is located in the recess and totally reflects light incident from the light emission region in the direction away from the optical axis. Thus, light emitted immediately upward from the light-emitting element having a high luminance does not travel toward the optical axis, thus reducing the luminance around the optical axis. The light-control lens further includes the first refractive surface that is located outside the first reflective surface in the recess and refracts light incident from the light emission region at an emission angle larger than an incident angle of the light. Thus, the luminance around the optical axis that has decreased due to total reflection on the first reflective surface can be corrected, and variations in luminance can be reduced as a whole.

In the example light emitting device, a reflection angle at the first reflective surface may increase as a distance from the optical axis increases.

In the example light emitting device, a refraction angle at the first refractive surface may increase as a distance from the optical axis increases.

In the example light emitting device, the light-control lens may include a second reflective surface that is located outside the first refractive surface in the recess and totally reflects light incident from the light emission region in a direction away from the optical axis, and a second refractive surface that is located outside the second reflective surface and refracts light incident from the light emission region at an emission angle larger than an incident angle of the light.

In the example light emitting device, the light-control lens may include a third refractive surface that is located outside the second refractive surface and refracts light incident from the light emission region at an emission angle smaller than an incident angle of the light.

In the example light emitting device, the light-emitting element may be rectangular in plan view, the light-control lens may have a flat portion facing a longer side of the light-emitting element, and the flat portion may be sloped toward the optical axis from a lower end to an upper end thereof, and serve as a fourth refractive surface that refracts incident light such that an incident angle of the incident light is smaller than an emission angle of the incident light. This configuration can reduce the luminance at longer sides of the light-emitting element so that the luminance at the longer sides is made equal to the luminance at the shorter sides of the light-emitting element.

The example light emitting device may further include: a reflector located on the board, surrounding the light-emitting element, having an upper end located above an upper surface of the light-emitting element, and configured to reflect light emitted sideways from the light-emitting element; a resin encapsulating part located in a region surrounded by the reflector, encapsulating the light-emitting element, and containing a phosphor; and a wire connecting a wire bonding part located outside the reflector on the board to an electrode located on the upper surface of the light-emitting element, wherein the resin encapsulating part may have an indentation above the light emission region of the light-emitting element, a height of the resin encapsulating part may gradually decrease from a portion around the indentation to a portion in contact with the reflector, an upper end of the resin encapsulating part may be located above an upper end of the reflector, and the wire may be in contact with an upper surface of the resin encapsulating part in the region surrounded by the reflector.

This configuration can increase the thickness of the resin encapsulating part containing the phosphor without an increase in the height of the reflector.

An example surface light source device according to the present disclosure includes a plurality of example light emitting devices described above, wherein the plurality of light emitting devices are arranged to have a lattice pattern.

### Embodiment

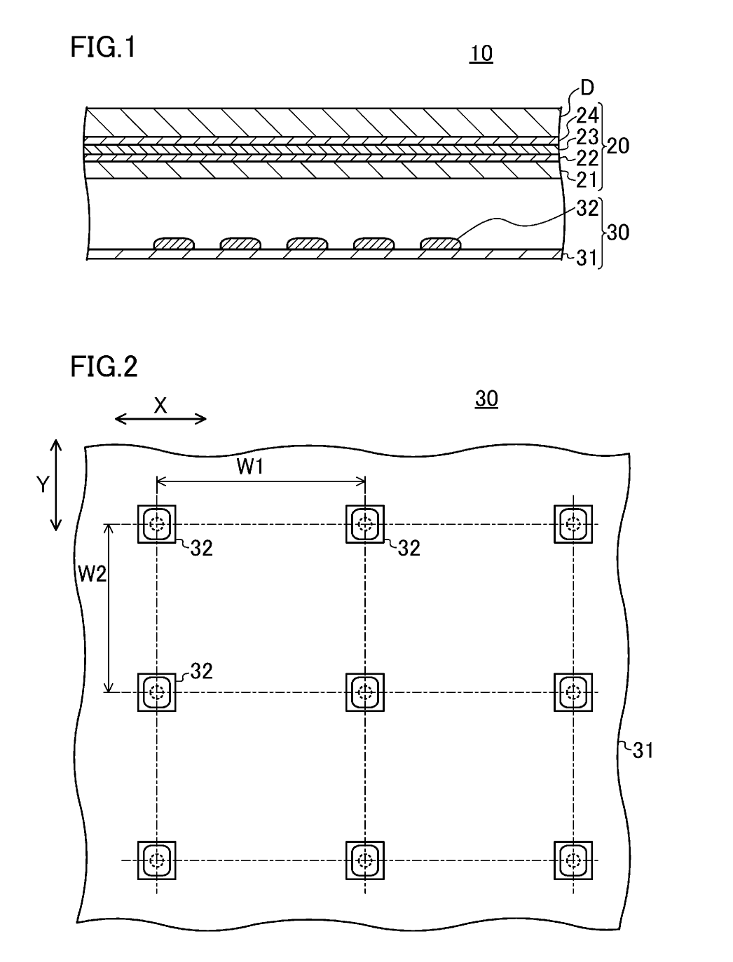

As illustrated in FIG. 1, a surface light source device 10 is a backlight device for illuminating, from behind, a liquid crystal panel D for use in, for example, a liquid-crystal television set with a wide screen in which a display screen has an aspect ratio of 16:9. The surface light source device 10 includes a light-control member 20 attached to the back surface of the liquid crystal panel D and also includes a surface light source part 30. The surface light source part 30 is located apart from the light-control member 20 at a predetermined distance.

The light-control member 20 includes a diffuser plate 21, a diffuser sheet 22, a first light-control sheet 23, and a second light-control sheet 24.

The diffuser plate 21 can be, for example, a resin plate having a coarse surface similar to frosted glass in order to diffuse light from the surface light source part 30. The diffuser plate 21 can be made of, for example, a polycarbonate (PC) resin, a polyester (PS) resin, or a cyclic olefin polymer (COP) resin.

The diffuser sheet 22 is provided to further diffuse light diffused by the diffuser plate 21, and can be made of a resin sheet of, for example, polyester.

The first light-control sheet 23 collects light diffused by the diffuser plate 21 and the diffuser sheet 22, and directs the collected light toward the liquid crystal panel D. The first light-control sheet 23 is a sheet having a prism surface. Specifically, the first light-control sheet 23 can be made of, for example, a polyester resin provided with triangular strips (i.e., linearly extending triangular projections) of an acrylic resin. The prism surface with the triangular strips can have a sawtooth profile in cross section. The second light-control sheet 24 collects light that has not been collected by the first light-control sheet 23. The second light-control sheet 24 reflects S waves toward the surface light source part 30 to increase the proportion of P waves that pass through the liquid crystal panel D, thereby increasing the accumulated light amount to increase the luminance. In this manner, the first light-control sheet 23 and the second light-control sheet 24 can reduce unevenness of brightness.

As illustrated in FIG. 2, the surface light source part 30 includes a mount board 31 and light emitting devices 32. The light emitting devices 32 are arranged in a matrix on the mount board 31. In this embodiment, the light emitting devices 32 are arranged with a spacing W1 in a direction X (i.e., the transverse direction) and with a spacing W2 in a direction Y (i.e., the longitudinal direction). The mount board 31 can be a printed wiring board in which a wiring pattern for supplying power to the light emitting devices 32 is formed on a large-size insulating substrate of, for example, an epoxy resin.

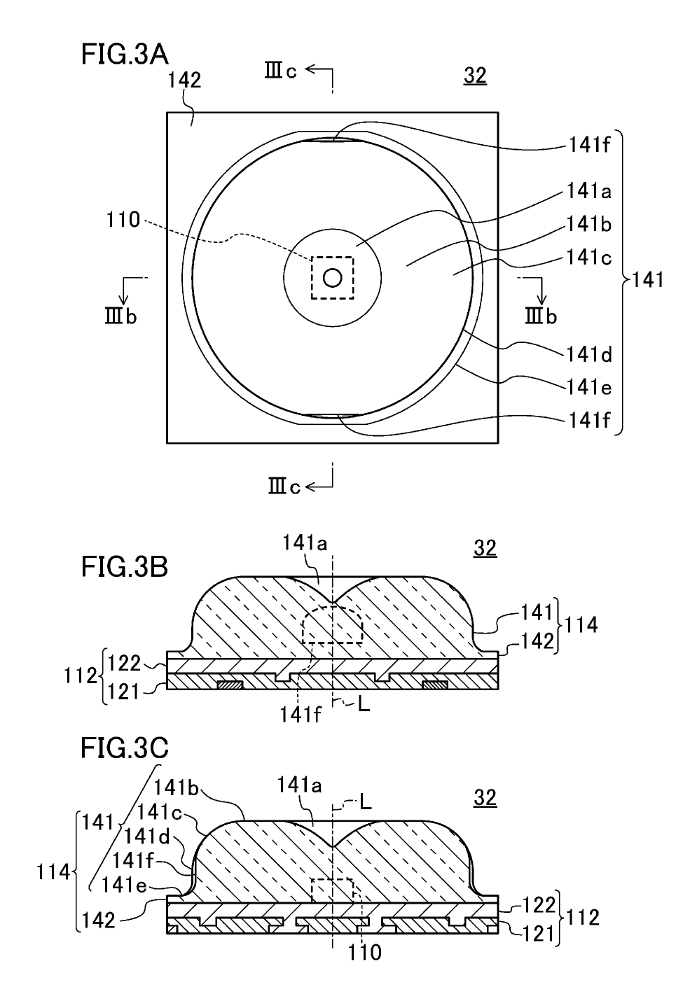

A configuration of the light emitting devices 32 of this embodiment will now be described in detail. As illustrated in FIGS. 3(a)-3(c), each of the light emitting devices 32 includes a light-emitting element 110 and a light-control lens 114, both of which are fixed (die-bonded) to a board 112. The light-control lens 114 is provided to have its optical axis coincide with that of a light emission region of the light-emitting element 110. Specifically, the center of the light emission region of the light-emitting element 110 is located immediately under the optical axis (the center axis) L of the light-control lens 114.

In this embodiment, the light-emitting element 110 has a substantially rectangular solid shape, and the upper surface of the light-emitting element 110 is substantially rectangular in plan view. The light-emitting element 110 can be, for example, a blue light-emitting diode. In general, the light-emitting element 110 includes a semiconductor layer and an electrode formed on a substrate. The semiconductor layer includes an n-type semiconductor layer, a light-emitting layer, and a p-type semiconductor layer, which are stacked in this order on the substrate. The electrode includes a p-side electrode in contact with the p-type semiconductor layer and an n-side electrode in contact with the n-type semiconductor layer. In this embodiment, the n-side electrode is formed on the n-type semiconductor layer exposed by etching the p-type semiconductor layer, the light-emitting layer, and part of the n-type semiconductor layer. In this embodiment, the p-side electrode and the n-side electrode are located at the opposed longer sides with the light emission region sandwiched therebetween. The light-emitting element 110 serves as a point light source that emits light from the light emission region by applying a voltage across the p-side electrode and the n-side electrode. The light emission region is actually a surface with a predetermined size, but is a very small region and thus, when being seen as a light emitting device 32, can be regarded as a point.

The light-control lens 114 is made of a silicon-based resin, and diffuses light emitted from the light-emitting element 110 to a wide range. The light-control lens 114 includes a substantially hemispherical lens portion 141 and a brim portion 142 located around the periphery of the lens portion 141 and having a square outer shape.

The lens portion 141 has a recess 141a around the optical axis L. In the recess 141a, the diameter at the upper end is larger than the diameter at the bottom, and the slope of the wall gradually becomes gentle from the bottom to the upper end.

The recess 141a is surrounded by a horizontal surface 141b that is substantially horizontal (i.e., substantially orthogonal to the optical axis L). The horizontal surface 141b is surrounded by an arc surface 141c that is a gently convex surface. The arc surface 141c is surrounded by a peripheral surface 141d that is substantially vertical. A bottom portion 141e having a gently concave curve is provided between the peripheral surface 141d and the brim portion 142. The peripheral surface 141d is partially cut out in the vertical direction, thereby forming flat portions 141f. The flat portions 141f are opposed to each other with the optical axis L sandwiched therebetween. The flat portions 141f are opposed to the longer sides of the light-emitting element 110. The flat portions 141f are slightly sloped toward the optical axis L from the bottom to the top thereof. In this embodiment, each of the flat portions 141f is sloped at about 2° with respect to the optical axis L.

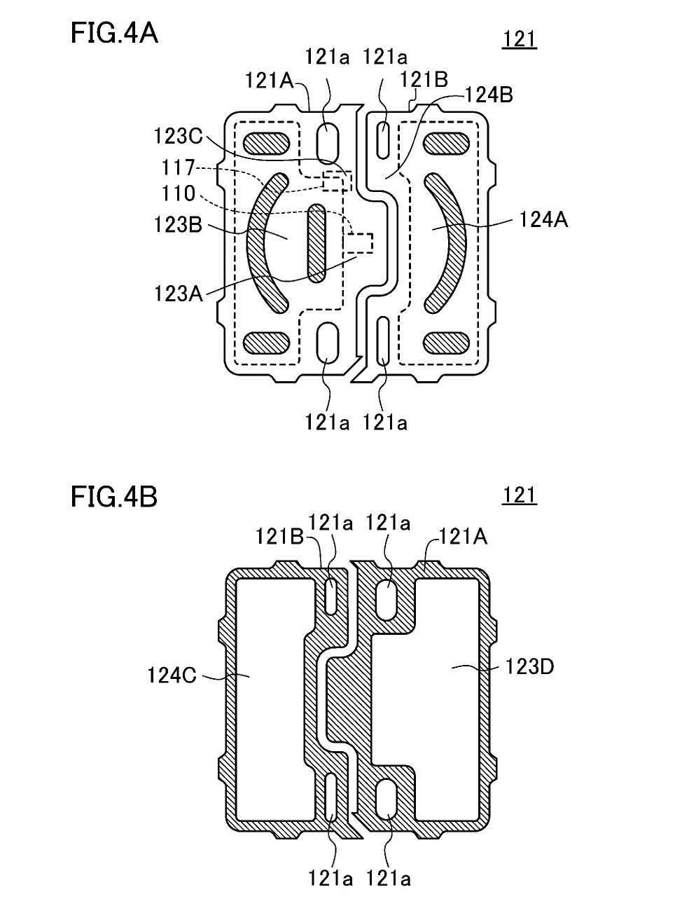

The board 112 has a lead frame 121 and a resin frame 122. The lead frame 121 may be a copper alloy plate obtained by patterning laminated plating layers of, for example, nickel or gold. As illustrated in FIGS. 4(a) and 4(b), the lead frame 121 has a substantially square outline. The lead frame 121 includes an anode frame 121A and a cathode frame 121B, which are integrally formed by means of the resin frame 122. Each of the anode frame 121A and the cathode frame 121B has two through holes 121a for preventing a shift from occurring when being integrally formed with the resin frame 122.

As illustrated in FIG. 4(a), a die bonding part 123A to which the light-emitting element 110 is fixed, a wire bonding part 123B to which a wire 116 connected to the p-side electrode of the light-emitting element 110 is bonded, and a protection-device die bonding part 123C to which a protection device 117 is fixed, are provided on one surface (a front surface) of the anode frame 121A. On the other hand, a wire bonding part 124A to which a wire 116 connected to the n-side electrode of the light-emitting element 110 and a protection-device wire bonding part 124B to which a wire 118 connected to the protection device 117 is bonded, are provided on a front surface of the cathode frame 121B.

As illustrated in FIG. 4(b), an anode electrode 123D is provided on the back surface of the anode frame 121A. A cathode electrode 124C is provided on the back surface of the cathode frame 121B.

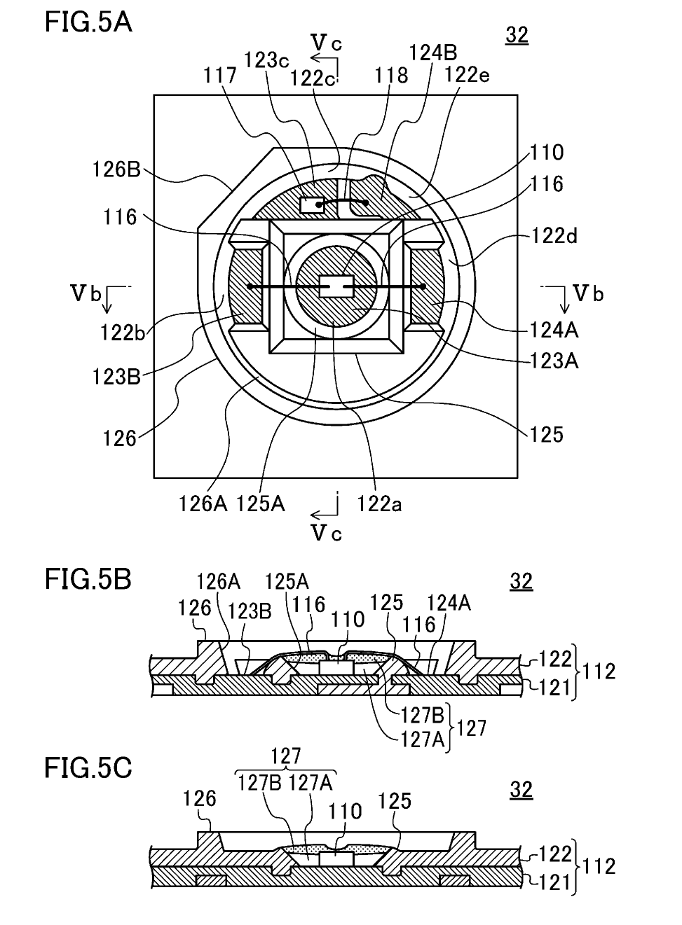

As illustrated in FIG. 5, the resin frame 122 is integrally formed with the lead frame 121. The resin frame 122 is preferably white in order to increase the reflection efficiency of light. The resin frame 122 can be formed by filling a cavity between upper and lower molds sandwiching the lead frame 121 with, for example, an epoxy resin, and then curing the epoxy resin.

A first opening 122a, which is circular in plan view, for exposing the die bonding part 123A of the lead frame 121 therein is formed at the center of the resin frame 122. The first opening 122a is formed to have its diameter gradually increase from the lower end to the upper end, and the wall of the first opening 122a is sloped. The first opening 122a is surrounded by a first projection 125 having a square shape in plan view. Accordingly, the wall of the first opening 122a is integrated with a side surface (i.e., the inner side surface) of the first projection 125 facing the first opening 122a to form a first reflective surface 125A that reflects upward part of light emitted from the light-emitting element 110 fixed to the die bonding part 123A. That is, the first opening 122a and the first projection 125 serve as a first reflector. The outer side surface of the first projection 125 has a slope such that the height of the first projection 125 gradually decreases. The first reflector is located immediately under the recess 141a formed in the light-control lens 114.

A second projection 126 having a circular shape in plan view and surrounding the light-emitting element 110 is provided outside the first projection 125. The inner side surface of the second projection 126 serves as a second reflective surface 126A, so that the second projection 126 serves as a second reflector. The second reflective surface 126A is sloped at an angle larger than the first reflective surface 125A. The second reflector reflects, for example, light not reflected by the first reflector and light reflected on the light-control lens 114 toward the board 112.

The first reflective surface 125A and the second reflective surface 126A are formed concentrically about the light-emitting element 110. The upper end of the second reflective surface 126A is located higher than the upper end of the first reflective surface 125A.

The outer side surface of the second projection 126 is partially cut out such that a straight portion 126B is formed. The straight portion 126B serves as a polarity indicator for enabling visual recognition of orientation of the electrodes of the light emitting device 32.

Between the first projection 125 and the second projection 126, a second opening 122b, a third opening 122c, a fourth opening 122d, and a fifth opening 122e for exposing the wire bonding part 123B, the protection-device die bonding part 123C, the wire bonding part 124A, and the protection-device wire bonding part 124B, respectively, are formed.

The p-side electrode of the light-emitting element 110 fixed to the die bonding part 123A exposed in the first opening 122a is connected to the wire bonding part 123B exposed in the second opening 122b by the wire 116. The n-side electrode of the light-emitting element 110 is connected to the wire bonding part 124A exposed in the fourth opening 122d by the wire 116. An electrode of the protection device fixed to the protection-device die bonding part 123C exposed in the third opening 122c is connected to the protection-device wire bonding part 124B exposed in the fifth opening 122e by a wire 118. The wires 116 and 118 may be, for example, gold (Au) fine wires.

An encapsulating resin is embedded in a region surrounded by the first projection 125, and a resin encapsulating part 127 encapsulating the light-emitting element 110 fixed to the die bonding part 123A is formed. The resin encapsulating part 127 includes a first encapsulating part 127A of, for example, a transparent silicone resin and a second encapsulating part 127B of, for example, a silicone resin containing a phosphor. The upper surface of the second encapsulating part 127B is in contact with the wires 116 connecting the p-side electrode and the n-side electrode of the light-emitting element 110 to the wire bonding part 123B and the wire bonding part 124A, respectively. Accordingly, the second encapsulating part 127B has its thickness gradually increase from the outer rim toward the center thereof in accordance with the shape of the wires 116, and has an indentation in a region between the wires 116 (i.e., immediately above the light emission region).

The presence of the second encapsulating part 127B containing a phosphor can convert light emitted from the light-emitting element 110 to light with another wavelength. For example, in a case where the light-emitting element 110 emits blue light, the use of a phosphor that is excited by blue light and emits yellow light as light of a complementary color can obtain white light as a mixture of blue light and yellow light. In this case, the phosphor can be, for example, a silicate phosphor or an yttrium aluminium garnet (YAG)-based phosphor.

The protection device 117 constitutes a protection circuit for protecting the light-emitting element 110 against overvoltage. In this embodiment, the protection device 117 is a Zener diode, but may be a diode, a capacitor, a resistor, or a varistor, for example. When the light-emitting element 110 has a sufficiently high breakdown voltage, the protection device 117 is not necessarily provided.

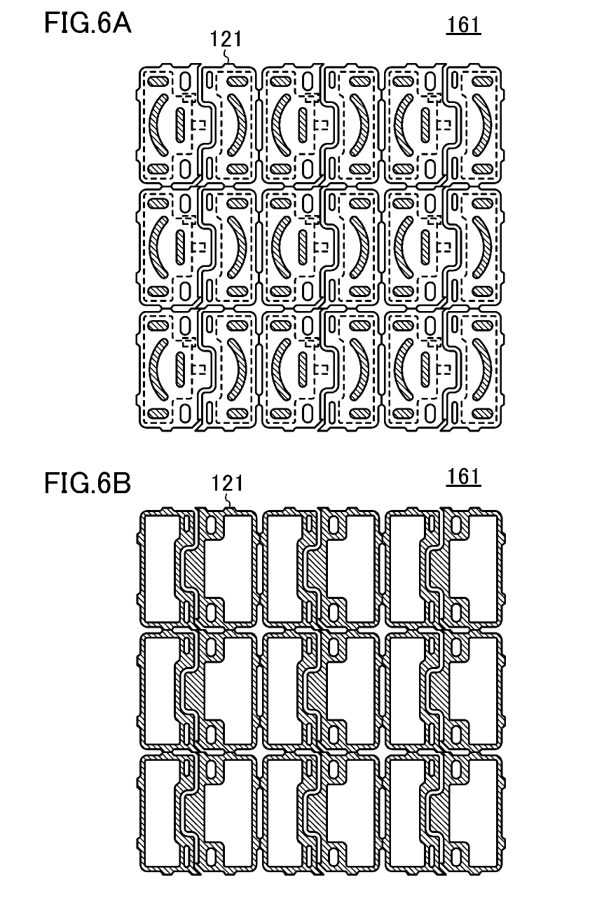

An example of a method for fabricating a light emitting device 32 will now be described. First, as illustrated in FIGS. 6(a) and 6(b), holes are punched in a metal plate, thereby forming a lead frame assembly 161 in which a plurality of lead frames 121 are arranged in columns and rows.

Next, the lead frame assembly 161 is clamped with a mold, and resin frames 122 are molded by transfer molding.

Then, light-emitting elements 110 are fixed (die-bonded) to die bonding parts 123A of anode frames 121A. In addition, protection devices 117 are fixed to protection-device die bonding parts 123C, and the protection devices 117 are connected to protection-device wire bonding parts 124B by wires 118.

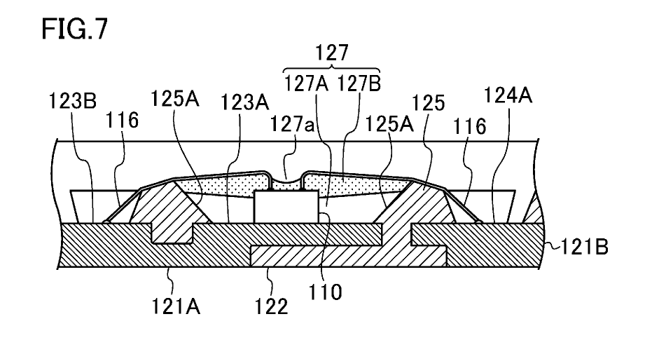

Thereafter, as illustrated in FIG. 7, a wire 116 is first bonded to the p-side electrode of each of the die-bonded light-emitting elements 110, and is raised vertically to a position above the upper end of the first projection 125. The wire 116 is further bent toward the first projection 125, and is second bonded to the wire bonding part 123B across the first projection 125, while being in contact with the upper end of the first projection 125. In the same manner, the n-side electrode of each of the die-bonded light-emitting elements 110 is connected to the wire bonding part 124A by a wire 116.

The above-described arrangement of the wires 116 can prevent an encapsulating resin from flowing out of a region surrounded by the first projection 125 in potting the encapsulating resin, and can keep the encapsulating resin raised. In FIG. 7, the wires 116 are in contact with the upper end of the first projection 125, but do not need to be in contact with the upper end of the first projection 125 as long as the encapsulating resin can be attached to the wires 116.

Subsequently, a first encapsulating resin of, for example, a transparent liquid silicone resin is potted into a region surrounded by the first projection 125, and then cured, thereby forming a first encapsulating part 127A. In potting the first encapsulating resin, the amount of the first encapsulating resin is adjusted such that the upper surface of the light-emitting element 110 is not covered with the first encapsulating resin.

After formation of the first encapsulating part 127A, a second encapsulating resin of, for example, a liquid silicone resin containing a phosphor is potted to cover the upper surface of the light-emitting element 110, and then cured, thereby forming a second encapsulating part 127B. When the second encapsulating resin is potted to a position near the upper end of the first projection 125, the second encapsulating resin is attached to the wires 116 in contact with the upper end of the first projection 125 and is raised, and thus extends to the upper end of the first projection 125. When the second encapsulating resin is further potted, the second encapsulating resin is lifted by the wires 116 vertically drawn from the upper surface of the light-emitting element 110. Thus, the upper surface of the second silicone resin is held by the wires 116, and is gradually raised from the outer rim toward the center of the region surrounded by the first projection 125. Above the light emission region of the light-emitting element 110, since no wires supporting the second encapsulating resin are present, an indentation is formed. By curing the second encapsulating resin in this state, the second encapsulating part 127B having its thickness gradually increase from the outer rim to the center and having an indentation 127a at the center thereof is formed.

The second encapsulating part 127B containing a phosphor is preferably relatively thick on the light-emitting element 110 in order to convert the wavelength of light efficiently. However, if the first projection 125 is excessively high, light travelling sideways is blocked. On the other hand, a configuration in which the wires 116 lift the encapsulating resin can ensure a sufficient thickness of the second encapsulating part 127B while reducing an increase in the height of the first projection 125. This configuration can also reduce an overflow of the second encapsulating resin across the first projection 125.

Since the wires 116 are connected to the p-side electrode and the n-side electrode located at both sides of the light-emitting element 110 with the center (i.e., the light emission region) thereof sandwiched therebetween, the indentation 127a is formed immediately above the light emission region. Accordingly, the indentation 127a is located immediately under the recess 141a provided in the light-control lens 114.

The wires 116 only need to be formed such that in potting the second encapsulating resin, the second encapsulating resin is made higher than the upper end of the first projection 125 by means of surface tension and lifting by the wires 116 to prevent the second encapsulating resin from overflowing across the first projection 125. Thus, although the wires 116 are in contact with the upper end of the first projection 125 in FIG. 7, the wires 116 do not need to be in contact with the upper end of the first projection 125 as long as the wires 116 are close to the upper end of the first projection 125.

Subsequently, using a mold having a cavity in the shape of the light-control lens 114, a light-control lens 114 is molded on a board 112 by transfer molding.

Then, the lead frame assembly 161 is diced into lead frames 121 with a dicer, thereby obtaining light emitting devices 32.

Before molding the light-control lens 114, a transparent liquid silicone resin, for example, may be potted onto a region surrounded by the second projection 126 to encapsulate the wires 116 and 118. The encapsulation of the wires 116 and 118 can reduce the possibility of disconnection of the wires 116 and 118 in forming the light-control lens 114.

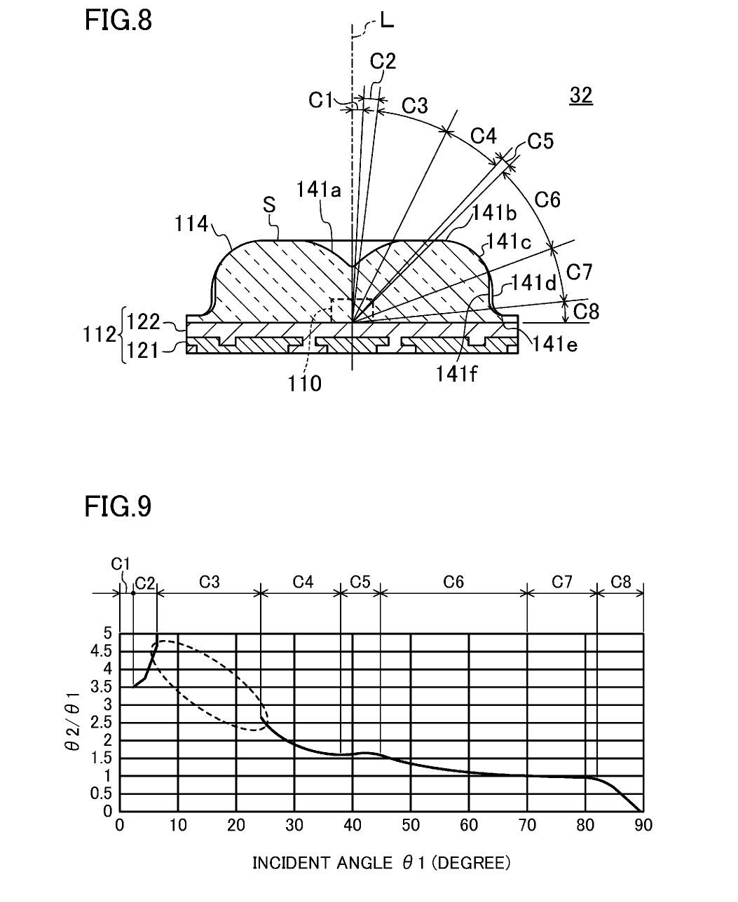

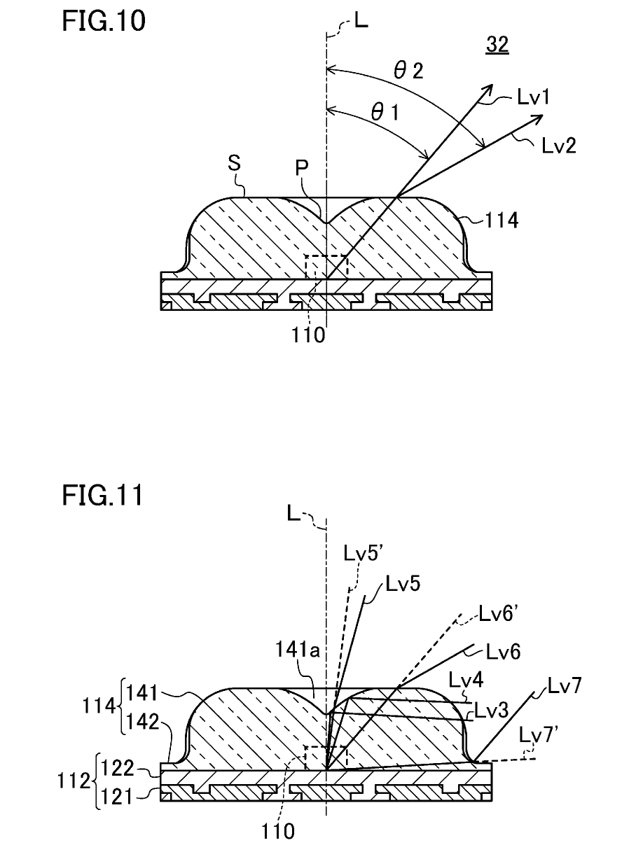

Then, the shape of the light-control lens 114 will be described. As illustrated in FIG. 8, eight regions C1-C8 are present on an emission surface S of the lens portion 141 of the light-control lens 114. The curves of the regions C1-C8 can be represented in FIG. 9 where the abscissa represents θ1 and the ordinate represents θ2/θ1. As illustrated in FIG. 10, θ1 is an incident angle of light from the light emission region of the light-emitting element 110. Specifically, θ1 is an angle formed by the optical axis L and a virtual line Lv1 indicating the direction in which light emitted from the light emission region of the light-emitting element 110 travels straight through the emission surface S. In addition, θ2 is an emission angle of light from the light emission region of the light-emitting element 110. Specifically, θ2 is an angle formed by the optical axis L and a virtual line Lv2 indicating the direction of refracted light obtained by refraction of light emitted from the light emission region of the light-emitting element 110 in the emission surface S. FIG. 9 shows characteristics along a line extending from an intersection of the emission surface S and the optical axis L to the bottom portion 141e through the flat portion 141f. The light-control lens 114 has a refractive index of 1.41.

The region C1 is a range having an angle θ1 of about 0°-3°, and corresponds to a portion near the bottom of the recess 141a. The region C1 serves as a reflective surface on which light incident from the direction of the light emission region of the light-emitting element 110 to the direction away from the optical axis L. In this region, the reflection angle increases as the distance from the optical axis L increases and the angle θ1 increases. Accordingly, light emitted immediately upward from the light-emitting element 110 is not directly emitted from the emission surface S of the light-control lens 114. Thus, it is possible to reduce a considerable rise of the emission intensity near the optical axis L.

In the indentation 127a of the second encapsulating part 127B containing the phosphor, the phosphor has a low efficiency of wavelength conversion. However, since the indentation 127a is located immediately under the recess 141a, light incident on the region C1 through the indentation 127a is reflected, and sufficiently mixed with the color of ambient light. Thus, advantageously, the difference in chromaticity caused by the indentation 127a can be made less visible from immediately above.

The region C2 is a range having an angle θ1 of about 3°-7°, and corresponds to a range from a portion near the bottom of the recess 141a to a portion near the lower end of the slope of the recess 141a. The region C2 is a refractive surface which has a high ratio θ2/θ1 and in which light incident from the direction of the light emission region is refracted to the direction away from the optical axis L. As the angle θ1 increases, the ratio θ2/θ1 increases and the refraction angle increases. Thus, in the region C2 that is a circumferential surface continuous to the outer periphery of the region C1, concentration of light to a portion near optical axis L can be avoided, and a decrease in emission intensity caused by total reflection of light in the region C1 can be compensated for.

The region C3 is a range having an angle θ1 of about 7°-24°, and corresponds to a range from a portion near the lower end of the slope of the recess 141a to a portion near the upper end of the recess 141a. The region C2 serves as a reflective surface on which light incident from the direction of the light emission region is totally reflected in the direction away from the optical axis L. In the same manner as in the region C1, as the angle θ1 increases, the reflection angle increases. Thus, in the region C3, light around the optical axis L is dispersed from the direction immediately above to the outward direction.

The region C4 is a range having an angle θ1 of about 24°-37°, and corresponds to a range from a portion near the upper end of the recess 141a to a portion near the middle of the horizontal surface 141b. The region C4 serves as a refractive surface which has a ratio θ2/θ1 greater than 1 (one) and in which light incident from the direction of the light emission region is refracted to the direction away from the optical axis L. However, the refraction angle is smaller than the angle θ2 (i.e., the ratio θ2/θ1 is about 1.5-2.5), and conversely to the region C2, as the angle θ1 increases, the refraction angle decreases. Thus, in the region C4, concentration of light to a portion near optical axis L can be avoided, and a decrease in emission intensity caused by total reflection of light on the region C3 can be compensated for.

The region C5 is a range having an angle θ1 of about 37°-43°, and corresponds to a portion near the middle of the horizontal surface 141b. The region C5 serves as a refractive surface in which light incident from the direction of the light emission region is refracted in the direction away from the optical axis L, and as the angle θ1 increases, the refraction angle slightly increases.

The region C6 is a range having an angle θ1 of about 43°-70°, and corresponds to a range extending from a portion near the middle of the horizontal surface 141b to the peripheral surface 141d and including the arc surface 141c. The region C6 serves as a refractive surface in which the refraction angle decreases as the angle θ1 increases. The ratio θ2/θ1 is 1 (one) near the boundary between the region C6 and the region C7.

The region C7 is a range having an angle θ1 of about 70°-82°, and corresponds to the flat portion 141f. The flat portion 141f is slightly sloped from the lower end to the upper end thereof to approach the optical axis L gradually. Accordingly, in the region C7, the ratio θ2/θ1 is less than 1 (one), and light incident from the direction of the light emission region is refracted toward the optical axis L. Since the flat portion 141f is located to oppose a longer side of the light-emitting element 110, light travelling sideways from the longer side of the light-emitting element 110 can be refracted toward the optical axis L, thereby increasing emission intensity immediately above the light-emitting element 110.

The region C8 is a range having an angle θ1 of about 82°-90°, and corresponds to the bottom portion 141e. In the region C8, the ratio θ2/θ1 is much less than 1 (one), and light incident from the direction of the light emission region is refracted toward the optical axis L. As the angle θ1 increases, the refraction angle increases.

As illustrated in FIG. 11, on the regions C1 and C3, light Lv3 and light Lv4 incident from the direction of the light emission region are totally reflected. In the region C2, when light Lv5 that is incident from the direction of the light emission region, passes through the emission surface S, and travels straight, is refracted outward relative to a line Lv5′. Similarly, in the regions C4-C6, the light Lv6 that is incident from the direction of the light emission region, passes through the emission surface S, and travels straight, is refracted outward relative to a line Lv6′. On the other hand, in the region C8, light Lv7 that is incident from the direction of the light emission region, passes through the emission surface S, and travels straight, is refracted upward (toward the optical axis L) relative to a line Lv7′. That is, the region C8 causes light travelling sideways from the light-emitting element 110 to be refracted toward the optical axis L to irradiate a region immediately above the light-emitting element 110.

Since the light emitting device 32 of this embodiment includes the second projection 126 as well as the first projection 125, light emitted from the light-emitting element 110 does not directly reach the bottom portion 141e. However, part of light reflected on the emission surface S of the light-control lens 114, for example, reaches the bottom portion 141e, and thus, a region immediately above the light-emitting element 110 can be irradiated. This configuration is expected to contribute to uniformization of the emission intensity.

The light-control lens 114 includes the region C1 on which light travelling from the light-emitting element 110 toward the optical axis L is totally reflected to a direction away from the optical axis L. This configuration can prevent the luminance in a region immediately above the light-emitting element 110 from being much higher than the luminance around this region. In addition, since light emitted from the light-emitting element 110 is refracted to a direction away from the optical axis L in the region C2 continuous to the outer periphery of the region C1, it is possible to compensate for a decrease in emission intensity due to total reflection of light on the region C1, while avoiding concentration of light around the optical axis L. Thus, even in a case where the light-emitting element 110 has a high luminance, variations in luminance can be reduced, resulting in uniformly irradiating a wide range.

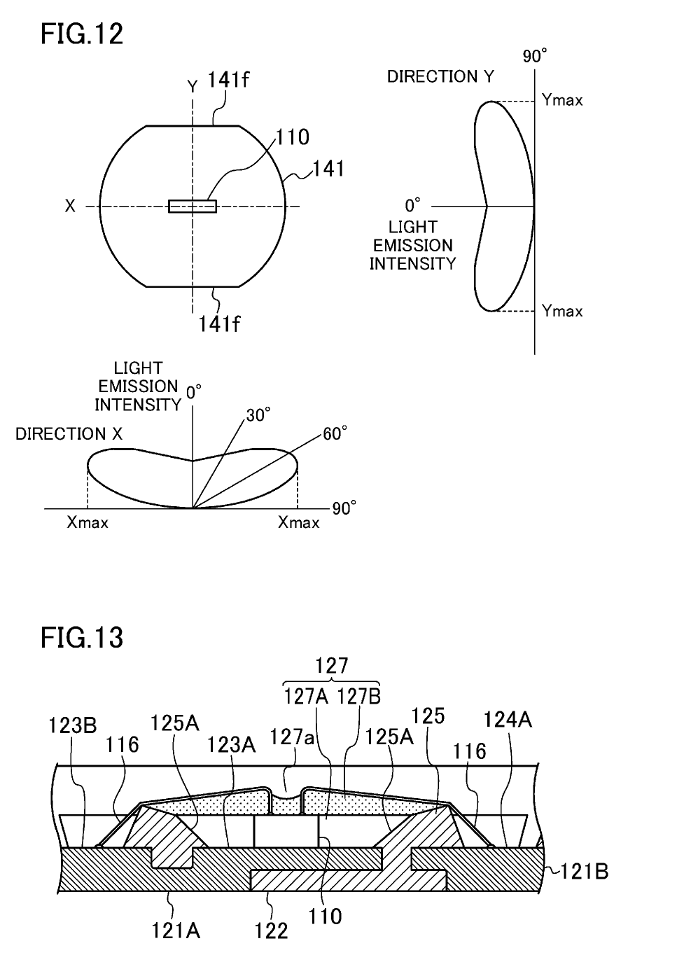

Luminance characteristics of the light emitting devices 32 will now be described. Since the light-emitting element 110 has a substantially rectangular solid shape, the luminance is higher in its longer sides than in its shorter sides. On the other hand, the light-control lens 114 has the flat portions 141f opposing the longer sides of the light-emitting element 110. Since the flat portions 141f do not have convex curves, the flat portions 141f have a small lens effect. Accordingly, as illustrated in FIG. 12, the degree of light convergence decreases at the longer sides of the light-emitting element 110 where the flat portions 141f are provided. Consequently, the maximum emission intensity Xmax in the direction X connecting both the shorter sides of the light-emitting element 110 is substantially equal to the maximum emission intensity Ymax in the direction Y connecting both the longer sides of the light-emitting element 110. In this manner, even in the case where the light-emitting element 110 has a substantially rectangular solid shape, the presence of the flat portions 141f in the light-control lens 114 can make the emission intensity at the longer sides substantially equal to that at the shorter sides, thus enabling substantially uniform irradiation in all the directions.

As described above, the light emitting device 32 of this embodiment can substantially uniformly distribute light to a region around the light-control lens 114. Accordingly, in the surface light source part 30 as illustrated in FIG. 2, the light emitting devices 32 can be evenly spaced from one another in each of the direction X and the direction Y. In addition, adjustment of light distribution in the direction X and the direction Y by adjusting the effect by the flat portions 141f can adjust the ratio between W1 and W2. In this case, the light emitting device 32 can be easily applied to, for example, a wide-screen display system.

In this embodiment, the inner side surface of the first projection 125 and the wall surface of the first opening 122a are sloped at the same angle, and the outer side surface of the first projection 125 is sloped at an angle different from that of the wall surfaces of the second opening 122b and the fourth opening 122d. Alternatively, as illustrated in FIG. 13, a configuration in which the inner side surface of the first projection 125 and the wall surface of the first opening 122a are sloped at different angles and the outer side surface of the first projection 125 and the wall surfaces of the second opening 122b and the fourth opening 122d are sloped at the same angle, may be employed. In the configuration illustrated in FIG. 13, the wires 116 are in point contact with the upper end of the first projection 125. In this configuration, however, the second encapsulating resin can be lifted by the wires 116 during potting, resulting in that the second encapsulating part 127B can be made thicker in its center than in its rim. In addition, since the inner side surface of the first projection 125 is sloped more gently than the wall surface of the first opening 122a, light can be distributed in a wider range than that in the configuration illustrated in FIG. 7. The outer side surface of the first projection 125 may be sloped at an angle different from that of the wall surfaces of the second opening 122b and the fourth opening 122d.

In this embodiment, two wires 116 are connected to the light-emitting element 110. However, the number of wires 116 only needs to be two or more. Since the effect of lifting the second encapsulating part 127B is large immediately under the wires 116, the second encapsulating part 127B is recessed in a region between the wires 116. Thus, an increase in the number of wires 116 to increase the number of locations at which the second encapsulating part 127B is lifted can more uniformly increase the thickness of the second encapsulating part 127B.

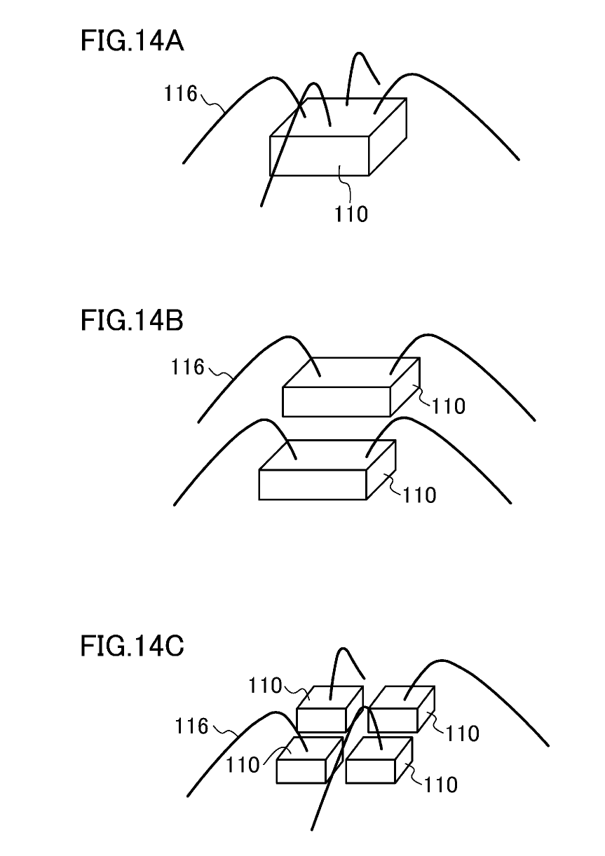

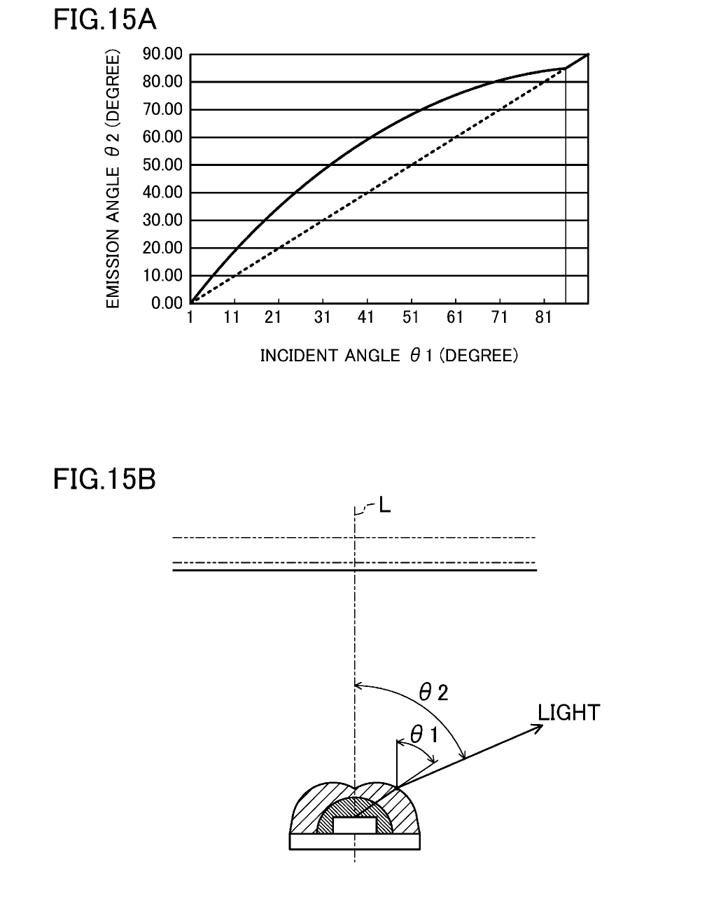

For example, as illustrated in FIG. 14(a), two wires 116 may be connected to each of the p-side electrode and the n-side electrode of the light-emitting element 110. In this case, the wires 116 are preferably shifted from each other by 90°. In this manner, a larger part of the second encapsulating part 127B can be lifted. The number of wires 116 connected to each of the p-side electrode and the n-side electrode may be three or more.

As illustrated in FIG. 14(b), a plurality of light-emitting elements 110 may be provided. In this case, even when a single wire is connected to each of the p-side electrode and the n-side electrode of each of the light-emitting elements 110, the number of wires 116 increases in total, thereby enhancing the effect of lifting the second encapsulating part 127B. Three or more wires may be connected to each of the light-emitting elements 110. The number of light-emitting elements 110 may be three or more.

In a case where a plurality of light-emitting elements 110 are provided, the n-side electrodes are provided toward the board 112 to be directly connected to the lead frame, while connecting the wires 116 to the p-side electrodes. FIG. 14(c) illustrates an example in which four light-emitting elements 110 are provided. In this example, the second encapsulating part 127B is lifted by four wires 116, thus making the thickness of the second encapsulating part 127B more uniform. Two or more wires may be connected to each p-side electrode. The n-side electrode and the p-side electrode are replaced with each other so that wires are connected to the n-side electrode.

### INDUSTRIAL APPLICABILITY

A light emitting device according to the present disclosure can provide a light emitting device having a wide optical illumination range and reduced variations in luminance, and is useful especially as, for example, a light emitting device for use in a backlight device, etc.

### DESCRIPTION OF REFERENCE CHARACTERS

10 surface light source device
20 light-control member
21 diffuser plate
22 diffuser sheet
23 first light-control sheet
24 second light-control sheet
30 surface light source part
31 mount board
32 light emitting device
110 light-emitting element
112 board
114 light-control lens
116 wire
117 protection device
118 wire
121 lead frame
121A anode frame
121B cathode frame
121a through hole
122 resin frame
122a first opening
122b second opening
122c third opening
122d fourth opening
122e fifth opening
123A die bonding part
123B wire bonding part
123C protection-device die bonding part
123D anode electrode
124A wire bonding part
124B protection-device wire bonding part
124C cathode electrode
125 first projection
125A first reflective surface
126 second projection
126A second reflective surface
126B straight portion
127 resin encapsulating part
127A first encapsulating part
127B second encapsulating part
127a indentation
141 lens portion
141a recess
141b horizontal surface
141c arc surface
141d peripheral surface
141e bottom portion
141f flat portion
142 brim portion
161 lead frame assembly

1-8. (canceled)

9. A light emitting device, comprising:
a light-emitting element fixed onto a board and having a light emission region that faces upward; and
a light-control lens located above the light-emitting element and having an optical axis that coincides with an optical axis of the light emission region, wherein
the light-control lens includes
a recess located around the optical axis,
a first reflective surface that is located in the recess and totally reflects light incident from the light emission region in a direction away from the optical axis, and
a first refractive surface that is located outside the first reflective surface in the recess and refracts light incident from the light emission region at an emission angle larger than an incident angle of the light.

10. The light emitting device of claim 9, wherein
a reflection angle at the first reflective surface increases as a distance from the optical axis increases.

11. The light emitting device of claim 9, wherein
a refraction angle at the first refractive surface increases as a distance from the optical axis increases.

12. The light emitting device of claim 9, wherein
the light-control lens includes
a second reflective surface that is located outside the first refractive surface in the recess and totally reflects light incident from the light emission region in a direction away from the optical axis, and
a second refractive surface that is located outside the second reflective surface and refracts light incident from the light emission region at an emission angle larger than an incident angle of the light.

13. The light emitting device of claim 9, wherein
the light-control lens includes a third refractive surface that is located outside the second refractive surface and refracts light incident from the light emission region at an emission angle smaller than an incident angle of the light.

14. The light emitting device of claim 9, wherein
the light-emitting element is rectangular in plan view,
the light-control lens has a flat portion facing a longer side of the light-emitting element, and
the flat portion is sloped toward the optical axis from a lower end to an upper end thereof, and serves as a fourth refractive surface that refracts incident light such that an incident angle of the incident light is smaller than an emission angle of the incident light.

15. The light emitting device of claim 9, further comprising:
a reflector located on the board, surrounding the light-emitting element, having an upper end located above an upper surface of the light-emitting element, and configured to reflect light emitted sideways from the light-emitting element;
a resin encapsulating part located in a region surrounded by the reflector, encapsulating the light-emitting element, and containing a phosphor; and
a wire connecting a wire bonding part located outside the reflector on the board to an electrode located on the upper surface of the light-emitting element, wherein
the resin encapsulating part has an indentation above the light emission region of the light-emitting element,
a height of the resin encapsulating part gradually decreases from a portion around the indentation to a portion in contact with the reflector,
an upper end of the resin encapsulating part is located above an upper end of the reflector, and
the wire is in contact with an upper surface of the resin encapsulating part in the region surrounded by the reflector.

16. The light emitting device of claim 15, wherein
a reflection angle at the first reflective surface increases as a distance from the optical axis increases.

17. The light emitting device of claim 15, wherein
a refraction angle at the first refractive surface increases as a distance from the optical axis increases.

18. The light emitting device of claim 15, wherein
the light-control lens includes
a second reflective surface that is located outside the first refractive surface in the recess and totally reflects light incident from the light emission region in a direction away from the optical axis, and
a second refractive surface that is located outside the second reflective surface and refracts light incident from the light emission region at an emission angle larger than an incident angle of the light.

19. The light emitting device of claim 15, wherein
the light-control lens includes a third refractive surface that is located outside the second refractive surface and refracts light incident from the light emission region at an emission angle smaller than an incident angle of the light.

20. The light emitting device of claim 15, wherein
the light-emitting element is rectangular in plan view,
the light-control lens has a flat portion facing a longer side of the light-emitting element, and
the flat portion is sloped toward the optical axis from a lower end to an upper end thereof, and serves as a fourth refractive surface that refracts incident light such that an incident angle of the incident light is smaller than an emission angle of the incident light.

21. A surface light source device, comprising
a plurality of light emitting devices of claim 1, wherein
the plurality of light emitting devices are arranged to have a lattice pattern.
